(19) United States
(12) Patent Application Publication
(10) Pub. No.: US 2005/0179077 A1
(43) Pub. Date: Aug. 18, 2005

(54) Monolithic integrated soi circuit with capacitor

(75) Inventor: Wolfgang Schnitt, Norderstedt (DE)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: Koninklijke Philips Electronics N.V., 5621 BA Eindhoven (NL)

(21) Appl. No.: 10/506,155

(22) PCT Filed: Feb. 26, 2003
(86) PCT No.: PCT/IB03/00726

(30) Foreign Application Priority Data
Mar. 7, 2002 (DE) 102 10 044.6

(51) Int. Cl. H01L 27/108; H01L 29/76; H01L 29/94

(52) U.S. Cl. 257/306

(57) ABSTRACT

A monolithic integrated circuit of SOI construction that is provided with an SOI substrate comprising an insulating layer, and a silicon semiconductor layer having monocrystalline domains, and with a capacitor that comprises a bottom electrode that is formed from a monocrystalline domain of the silicon semiconductor layer and a layer containing a silicide, a capacitor dielectric formed over the layer containing a silicide, and a top electrode formed over the capacitor dielectric.

The invention relates to a monolithic integrated circuit of SOI construction that comprises an SOI substrate and a capacitor having a bottom electrode, a dielectric and a top electrode.

A major problem affecting integrated circuits of conventional construction is the degradation of the electric properties of the active and passive components as the structure become increasingly fine, this being due to parasitic capacitances between the given component and the silicon substrate and between the components.

The SOI (silicon on insulator) method of construction provides a solution to this problem in that each individual component is produced in a thin, totally insulated island of silicon. Because there is no connection between the islands, no latch-up effect can occur and because the active function of the transistors is confined to the thin silicon film the short-channel effects are moderated. Also, the SOI technique enables passive components such as capacitors, coils and resistors to be incorporated in the integrated circuit and as a result it is possible for the degree of integration of the circuit to be increased.

There are a vast number of known capacitor structures for integrated circuits, which depend on the particular desired application of the circuit. The simplest capacitor structure is a diode that is biased in the reverse direction but whose capacitance greatly depends on the applied voltage.

Useful properties are provided by a capacitor that comprises two electrodes insulated from one another by a dielectric and that is constructed on a thick SiO₂ layer of the substrate. Its bottom electrode is generally composed of highly-doped polycrystalline silicon, the dielectric of silicon nitride and the top electrode of the usual metallization. Because of the SiO₂ base, there is not the leakage current at a p-n junction that is a nuisance above all at high temperatures.

Also available in semiconductor technology as capacitors for integration into monolithic integrated circuits are ones of substrate/polysilicon, substrate/aluminum, polysilicon/aluminum and metal/metal construction.

Although the reduced parasitic capacitance is a reason for the introduction of the SOI construction, parasitic capacitances do still exist between the substrate and the circuit components in the semiconductor layer. Passive circuit components in particular, such as capacitors, which from the point of view of size are considerably larger than typical active circuit components, are more prone, to a corresponding degree, to the effect of parasitic capacitance. Whereas the dimensions of active components approach the sub-0.5 μm range, it is unlikely that passive components will ever be smaller than 100 μm. Hence in wireless communication applications, where passive components of this and other kinds are usually required, capacitors are typically 100 times larger than any active circuit component.

The disadvantageous consequences of the parasitic capacitance affect the performance of the circuit by reducing the Q factor of the passive components and increase the overall losses of the circuit. What is more, the parasitic capacitance adds to any designed-in capacitances, and this also degrades the performance of the circuit. These problems show up with particular clarity when the integrated circuit is operated at high frequencies of the kind typically encountered in modern-day RF communications circuits and digital high-speed integrated circuits.

There is therefore a need for the parasitic capacitances to be reduced in monolithic integrated circuits of SOI construction that are used for RF and other high-frequency applications.

Known from WO 0057484 is a capacitor in an integrated circuit, which capacitor comprises an SOI substrate, a doped epitaxial layer of a first conductivity type that is formed on the SOI substrate and forms the first plate of the capacitor, an oxide layer that is formed on the doped epitaxial layer and is used as the dielectric layer of the capacitor, and a layer of polysilicon that is formed on the oxide layer and is used as the second plate of the capacitor.

It is true that in the prior art mentioned the doping of the epitaxial layer used for the first plate (electrode) of the capacitor increases the conductivity of the plate, but the conductivity achieved is far from being that of a metal. Because the thickness of the bottom layer of silicon is limited to less than 1.5 μm in the usual integrated circuits of SOI construction, the terminal resistance of a capacitor of this kind is still so high as to make a monolithic integrated circuit having such a capacitor unsuitable for applications in the high-frequency range from several hundred megahertz to gigahertz.

It is an object of the present invention to provide a monolithic integrated circuit of SOI construction having an integrated capacitor, which circuit is suitable for use as a high-frequency circuit.

In accordance with the invention, this object is achieved by a monolithic integrated circuit of SOI construction that is provided with an SOI substrate comprising an insulating layer, and a silicon semiconductor layer having monocrystalline domains, and with a capacitor that comprises a bottom electrode formed from a monocrystalline domain of the silicon semiconductor layer and a layer containing a silicide, a capacitor dielectric formed over the layer containing a silicide, and a top electrode formed over the capacitor dielectric.

An advantage of the present invention lies in the fact that the series resistance of the bottom electrode of the capacitor is significantly reduced in comparison with that of prior art capacitors.

A measure of the frequency-dependent energy loss and hence of the suitability of the capacitor for high-frequency applications is the quality factor Q≈2πC/R. The layer containing a silicide is a crystalline layer of a conductivity similar to that of a metal. Hence the energy loss caused by the silicide layer is less than with the doped epitaxial layer of the prior art. As a result, the terminal resistance ≈R of the capacitor is reduced and the quality factor Q improved.

Also, the stability problems that may occur with doped electrodes are avoided.

The capacitor in the monolithic integrated circuit according to the invention is not dependent on voltage, because the width of the space-charge layer is limited due to the monocrystalline silicon substrate.

The bottom electrode of the capacitor is insensitive to temperature, and as a result CVD processes whose deposition temperatures are above 600° C. can be used to form the dielectric of the capacitor.

In a preferred embodiment of the invention, the capacitor dielectric contains a dielectric material from the group silicon nitride, silicon oxide and silicon oxynitride and is formed by an LPCVD process at a deposition temperature T of more than 600° C.

It may also be preferred for the capacitor dielectric to comprise a layered structure composed of layers that contain a dielectric material from the group silicon nitride, silicon oxide and silicon oxynitride.

It may further be preferred for the capacitor dielectric to contain a dielectric material from the group TiOₓ, Ta₂O₅, AlN, barium nitrate, lead titanate and lead lanthanum zirconium titanate.

In the context of the present invention, it may be preferred for the layer containing a silicide to contain a silicide from the group of silicides TiSi₂, MoSi₂, WSi₂, TaSi₂, PtSi, PdSi₂, CoSi₂, NbSi₂, NiSi₂ and the silicides of the rare earths. These silicides have a low electrical conductivity, are easy to manufacture, form smooth surfaces and are resistant to corrosion.

It is particularly preferred for the material of the top electrode to comprise a metal. A top electrode of aluminum in particular can be produced economically and has the advantage that its makes the maximum allowance for compatibility requirements.

In the capacitor detailed in WO 0057484, the top electrode is formed from a doped layer of polycrystalline silicon. Due to the subsequent heat treatment, the dopant in this doped layer of polycrystalline silicon diffuses into the insulating layer of the capacitor, which results in the quality of the insulating layer of the capacitor being adversely affected, which in turn reduces capacitance and the breakdown voltage. This is avoided by the solution according to the invention.

It may also be preferred for the monolithic integrated circuit to comprise a via to the bottom electrode.

These and other aspects of the invention are apparent from and will be elucidated with reference to the embodiments described hereinafter.

In the drawings:

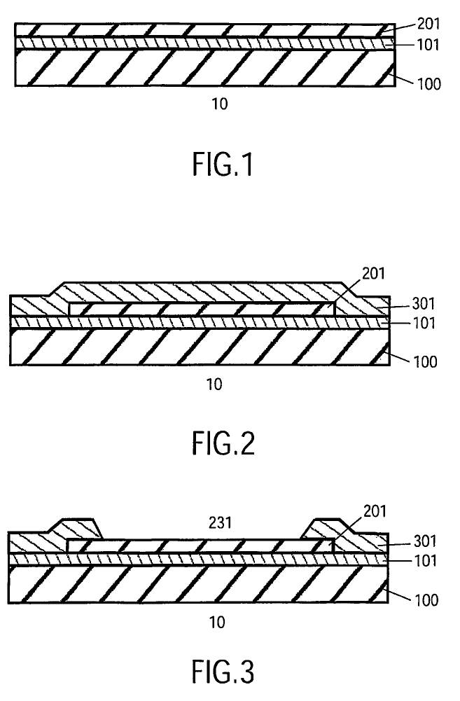

FIGS. 1 to 9 show details of a capacitor-equipped integrated circuit according to the invention in cross-section illustrating the production of a capacitor according to the present invention.

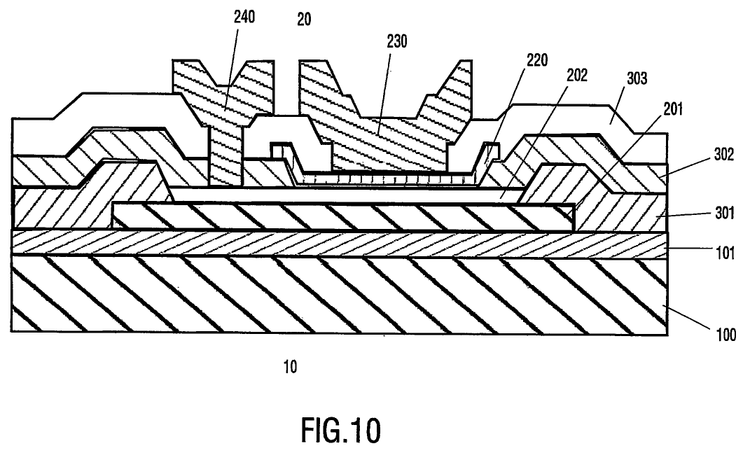

FIG. 10 shows a detail of a capacitor-equipped integrated circuit according to the invention in cross-section.

The monolithic integrated circuit comprises active and passive components. The form taken by the active circuit components is the usual one and will therefore not be described.

As is shown in FIG. 1, the manufacture of the circuit according to the invention begins with the production of the SOI substrate, i.e. with the formation, on a silicon handling substrate 100, of a layer of silicon 201 that is a monocrystalline layer of monosilicon, and of a buried insulating layer of oxide 101. The monocrystalline layer of monosilicon 201 and the insulating layer together form the silicon-on-insulator (SOI) substrate.

The SOI substrate can be produced by any of the conventional production processes. A successful process for producing high-quality SOI substrates is the SIMOX process. This is based on the high-dosage implantation of oxygen ions in weakly doped n-type or p-type silicon wafers to produce a buried, electrically insulating layer of SiO₂ below the surface of the wafer. Alternatively, the SOI substrate may be produced by wafer bonding, for which the point of departure is two thermally oxidized silicon wafers that are applied to one another under pressure and are firmly connected together mechanically by anodic or thermal bonding. By etching one of the two silicon wafers away to a thickness of a few micrometers, there is produced a layer of crystalline silicon on an SiO₂ insulator.

Another known process that is suitable for producing the SOI substrate is the FIPOS (full isolation by porous oxidized silicon) technique, which makes use of the high rate of oxidation of layers of porous silicon to produce islands of monocrystalline silicon in an oxide insulator.

Other suitable but expensive processes for producing the SOI substrate are the ELO (epitaxial lateral overgrowth) process in which a thermally grown layer of oxide on a silicon wafer is structured into islands that, starting from the silicon substrate, are coated over by a lateral growth of crystals in a subsequent epitaxial process, and the SOS process, which is a hetero-epitaxial process in which a wafer of monocrystalline silicon is grown in crystalline insulators such as sapphire or spinel by means of silicon epitaxy.

Basically, an SOI substrate can also be produced by a recrystallization process in which high-purity silicon is deposited on an insulating substrate as a polycrystalline silicon film and is then converted into monocrystalline silicon by a recrystallization process employing high-energy radiation. However, none of the recrystallization processes produce SOI substrates of other than limited quality because the size of the monocrystalline domains is a few square centimeters at most.

The thickness of the buried oxide layer (insulating layer) is preferably between 0.3 and 3 μm and the thickness of the layer of monocrystalline silicon between 0.1 and 4 μm.

Reference will now be made to FIG. 2. Starting from the SOI substrate, the production of the integrated components begins first with the structuring—using photosensitive resist as a mask—of the layer of monocrystalline silicon for the bottom electrode of the capacitor. There are two variant forms that the process can take in this case:
a) the silicon between the islands for the electrodes and other active and passive circuit components can all be removed by the dry etching process;
b) approx. 55% of the thickness of the film of monocrystalline silicon can be removed by the dry etching process and the rest of the film between the islands can then be converted into an oxide by the LOCOS process.

This is followed by the doping of the islands of monocrystalline monosilicon with boron or phosphorus as dictated by the transistors to be carried. The islands for the bottom electrodes 201 are preferably doped with antimony. The implantations in question may be performed under the control of ion energy, in a targeted way close to the surface, and centrally or at the rear face of the layer of monocrystalline silicon.

Once these stages of processing have been completed, a relatively thick, first insulating layer composed of a first insulating material 301 is deposited over the surface of the component. This thick insulating layer marks off the capacitor from the other integrated components on the substrate. For it, a layer of silicon oxide may for example be deposited by chemical deposition from the vapor phase, using a TEOS (tetraethyl orthosilicate) gas source, to a thickness of approximately 3000 angstroms. The next step is for an etching mask of photosensitive resist (not shown in the Figures) to be formed over the insulating layer and part of the insulating layer to be removed, thus producing an opening in the insulating layer. The insulating layer is preferably wet-etched in a substantially isotropic manner using an acid containing hydrogen fluoride. It may also be etched anisotropically by reactive ion etching (RIE) using CF₄ as a source gas, if the insulating layer is composed of silicon oxide.

FIG. 3 shows that part of the surface of the layer of monosilicon is exposed by the etching process at the etched trench 231.

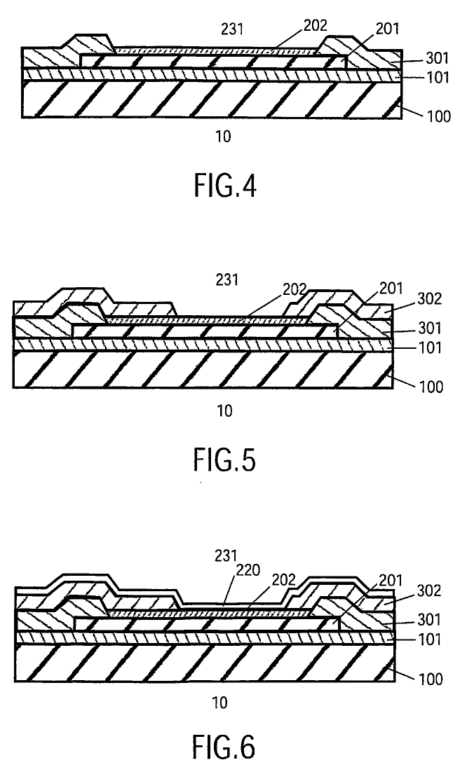

Reference will now be made to FIG. 4. The etched trench 231 is then partly filled again with a layer 202 containing a silicide.

Silicides are metal/silicon compounds that are used in silicon technology for low-resistance circuit-board conductors and contacts that are stable at temperature. There are many options for the metal selected for the layer containing a silicide. The silicides most frequently used are MoSi₂, WSi₂, TaSi₂ and TiSi₂, and PtSi and PdSi₂. As well as these, CoSi₂, NbSi₂, NiSi₂ and the silicides of the rare earths may also be mentioned. In the context of the present invention, preferred designs make use of titanium or cobalt.

The following processes in particular are available for the production of silicide layers:
salicidation
vapor deposition of a metal on silicon followed by reaction at elevated temperature
sputtering
deposition from the gas phase (the CVD process)
molecular beam epitaxy, and
ion implantation.

In a preferred production process, the layer containing a silicide is produced by salicidation. For this purpose, a layer of metal, preferably titanium, is first formed on the monosilicon by sputtering, over the whole of the component. The silicidation proper then takes place. As a result of a first heat treatment, a first-phase silicide forms by reaction with the monosilicon on the section in contact with the layer of monosilicon 201. There is no reaction with the insulating layer containing SiO₂. In the next step the metal that has not been converted into silicide is selectively removed. In a second heat treatment, the first-phase silicide is fully silicized and in the course of this develops a minimum resistivity. The use of salicidation as a production process also allows additional and costly photolithographic steps to be avoided.

In another production process, the layer containing a silicide may be generated on the monosilicon by sputtering. For this purpose, a layer of metal, preferably titanium, is formed on the monosilicon by sputtering through a mask. The silicidation proper is then performed by means of a heat treatment, such as for example annealing at a temperature of 820° C. for 30 seconds in an atmosphere of nitrogen. As a result, a finely crystalline layer 202 containing a silicide is formed on the section of the layer of monosilicon 201, and the layer 202 containing a silicide is thus in contact with the island of monosilicon.

In another production process, the CVD process may be used for the layer containing a silicide.

The layer containing a silicide is typically 0.1 to 0.2 μm thick and thus gives a sheet resistance of between 0.7 and 1.8 Ω/square, a value that is one to two orders of magnitude lower that the value for layers of highly-doped monosilicon of this thickness.

The second and third insulating layers 302 and 303 and the capacitor dielectric 220 are applied to this supporting structure.

The second insulating layer that rests on the first insulating layer is usually a relatively thick layer as well. For it, a layer of silicon oxide may likewise be deposited by chemical deposition from the vapor phase, using a TEOS (tetraethyl orthosilicate) gas source, to a thickness of approximately 3000 angstroms.

Reference will now be made to FIG. 5. By photolithographic structuring of a resist mask above the second insulating layer 302, an opening is now formed in the second insulating layer 302 in such a way that a section of the surface of the bottom electrode is again exposed.

When the opening is being etched in the second insulating layer 302, it should be ensured that a large margin is left to provide space for the contact hole for making contact from the surface with the bottom electrode.

As is shown in FIG. 6, the capacitor dielectric 220 is then formed. In a preferred design, the capacitor dielectric comprises a layer of silicon nitride that is produced by a low-pressure CVD process, such as from SiH₂Cl₂ and NH₃ at 300-400 millitorr and 700 to 800° C. The dielectric 220 is preferably thin and its thickness is between approximately 10 and 100 nm.

A suitable dielectric may for example also be an oxide layer that is formed by an HTO (high-temperature oxide) process in accordance with the reaction equation SiH₂Cl₂+2 N₂O→SiO₂+gases at between 800 and 900° C. Alternatively, what may be used for the dielectric is a series of thin dielectric layers that comprise approximately 70 angstroms of silicon nitride and approximately 20 angstroms of silicon oxide and that form a two-layer “NO” dielectric, or that comprise a very thin layer of silicon oxide, silicon nitride and silicon oxide (an “ONO” dielectric). Other films having a high dielectric constant may also be used. It is for example probable that TiOₓ, Ta₂O₅, AlN or barium titanate, lead titanate and lead lanthanum zirconium titanate barium titanate may be preferred if these materials can be produced with sufficient reliability and to sufficiently high standards of uniformity.

The capacitor dielectric is so formed over the whole surface that it is in contact with a section of the surface of the lower electrode through the opening 231.

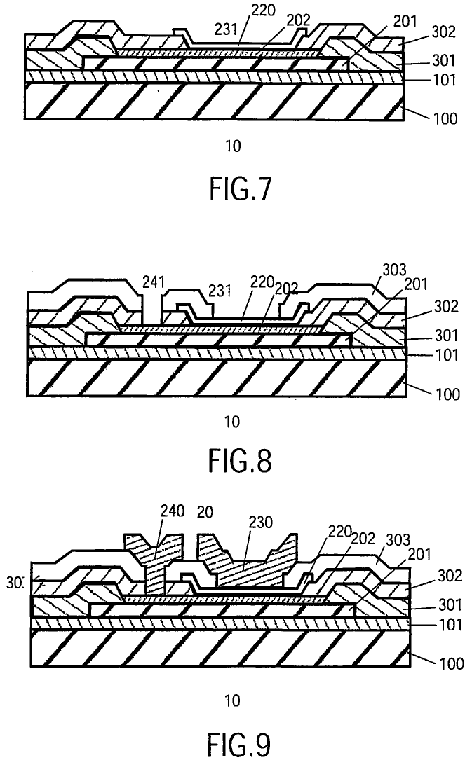

The layer of capacitor dielectric is then patterned in a desired form by photolithography, as shown in FIG. 7. In particular the capacitor dielectric is removed in the area where the contact with the bottom electrode will subsequently be formed.

As shown in FIG. 8, a third insulating layer 303 is then applied. The third insulating layer is usually a layer of silicon dioxide that is produced from SiH₄ and N₂O by a plasma-enhanced process at 300 to 350° C. using plasma excitation at for example 380 kHz and 15 kW.

There are also a range of other processes available for the deposition of the silicon oxide, such as deposition from tetraethyl orthosilicate in a hot-walled reactor, deposition from silane and oxygen by a CVD process at low temperatures, deposition from silane and a compound of nitrogen and oxygen at high temperatures, or deposition by a spin-on process from suitable starting compounds (spin-on glass). Polyimide or BCB may also be used for the third insulating layer.

Other combinations of materials may also be used to build up the layered structure formed by the three insulating layers 301, 302 and 303. However, there are a range of compatibility requirements that have to be met, relating particularly to diffusion, adhesion and selective etchability as described above and to mechanical and thermal stresses.

A section of the surface of the capacitor dielectric is again exposed by structuring the insulating layers. A second section exposes the area 241 for contact with the silicidized bottom electrode.

In a further step of the process, the metallization is applied, generally by sputtering on high-purity aluminum. Other suitable metals are copper, tungsten and alloys of aluminum with silicon and copper.

In a preferred design, a metal, e.g. aluminum is deposited and structured to form contacts 240 and 230. What has been found to be optimum is a layer of high-purity aluminum that is sputtered on at the lowest possible residual gas pressure, i.e. even without any reaction gas. At film thicknesses of 1.2 μm, sheet resistances of R_{f}<0.025 ohms are obtained in this way.

To prevent spikes from forming, the contact 240 with the bottom electrode may also comprise a diffusion barrier layer between the layer containing a silicide and the metallization.

Use may however also be made of many conventional materials to form the top electrode. To those skilled in the art it will be clear that as an alternative the top electrode may include a layer of polysilicon under a layer of metal in contact with the capacitor dielectric, such as is used in a double polysilicon capacitor structure.

Finally, the metallization is generally protected against physical attack, corrosion and ion contamination by a protective layer. For this purpose the component is covered with a layer composed of silicon nitride or SiO₂ deposited by a PECVD process, of phosphorus silicate glass, of BCB or of polyimide.

FIG. 9 shows, in cross-section, a fully formed capacitor according to a preferred embodiment of the present invention.

The covering layer 201 of monocrystalline silicon is doped on an SOI substrate 100 and is formed into a bottom electrode layer for the bottom electrode of the capacitor. A layer 202 containing a silicide is deposited on the bottom electrode layer. The bottom electrode has a stacked structure made up of a doped layer of monosilicon and a layer containing a silicide. A dielectric separating layer to form the capacitor dielectric 220 covers the bottom electrode. Arranged on the dielectric separating layer is the top electrode 230. A surface contact for the bottom electrode is formed by means of a via. The two electrodes and the dielectric separating layer for the capacitor dielectric form the capacitor. Like the top electrode, the bottom electrode is connected to the source of potential via a top-face contact.

1. A monolithic integrated circuit of SOI construction that is provided with an SOI substrate comprising an insulating layer, and a silicon semiconductor layer having monocrystalline domains, and with a capacitor that comprises a bottom electrode that is formed from a monocrystalline domain of the silicon semiconductor layer and a layer containing a silicide, a capacitor dielectric formed over the layer containing a silicide, and a top electrode formed over the capacitor dielectric.

2. A monolithic integrated circuit of SOI construction as claimed in claim 1, characterized in that the capacitor dielectric contains a dielectric material from the group silicon nitride, silicon oxide and silicon oxynitride.

3. A monolithic integrated circuit of SOI construction as claimed in claim 1, characterized in that the capacitor dielectric is a layered structure composed of layers that contain a dielectric material from the group silicon nitride, silicon oxide and silicon oxynitride.

4. A monolithic integrated circuit of SOI construction as claimed in claim 1, characterized in that the capacitor dielectric contains a dielectric material from the group TiOₓ, Ta₂O₅, AlN, barium titanate, lead titanate and lead lanthanum zirconium titanate.

5. A monolithic integrated circuit of SOI construction as claimed in claim 1, characterized in that the capacitor dielectric is formed by an LPCVD process at T>600° C.

6. A monolithic integrated circuit of SOI construction as claimed in claim 1, characterized in that the layer containing a silicide contains a silicide from the group of silicides TiSi₂, MoSi₂, WSi₂, TaSi₂, PtSi, PdSi₂, CoSi₂, NbSi₂, NiSi₂ and the silicides of the rare earths.

7. A monolithic integrated circuit of SOI construction as claimed in claim 1, characterized in that the material of the top electrode comprises a metal 8. A monolithic integrated circuit of SOI construction as claimed in claim 1, characterized in that it comprises a via to the bottom electrode.
